(19) United States
(12) Patent Application Publication
(10) Pub. No.: US 2009/0262954 A1
(43) Pub. Date: Oct. 22, 2009

(54) AUDIO SIGNAL ADJUSTING METHOD AND DEVICE UTILIZING THE SAME

(75) Inventor: Wen-Long LIN, Tainan County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: HIMAX TECHNOLOGIES LIMITED, Tainan County (TW)

(21) Appl. No.: 12/104,639

(22) Filed: Apr. 17, 2008

(51) Int. Cl. H03G 3/20

(52) U.S. Cl. 381/107

(57) ABSTRACT

An audio signal adjusting device is disclosed. The audio signal adjusting device for adjusting the amplitudes of digital audio signals received from a decoder that decodes the audio signals received from an antenna comprises a buffer, a signal abnormality detector and a fading processor. The buffer stores the digital audio signals received from the decoder. The signal abnormality detector detects the abnormality of the digital audio signals stored in the buffer and outputs a fading out enable instruction when the digital audio signals are detected as abnormal. The fading processor fades out the amplitudes of the digital audio signals stored in the buffer according to a fading out algorithm after receiving the fading out enable instruction, to output faded digital audio signals.

### BACKGROUND OF THE INVENTION

1. Field of the Invention

The invention relates to an audio signal adjusting device, and more particularly to audio signal adjusting device in a digital television broadcasting system.

2. Description of the Related Art

Digital television (DTV) broadcasting system is a telecommunication system for broadcasting and receiving moving pictures and sound by means of digital signals, in contrast to analog signals used by traditional analog TVs. DTV uses digital modulation data, which is digitally compressed and requires decoding by a specially designed television set, or a standard receiver with a set-top box, or a PC fitted with a television card. Introduced in the late 1990s, this technology appealed to the television broadcasting business and consumer electronics industries as offering new financial opportunities.

Standard definition TV, by comparison, may use one of several different formats taking the form of various aspect ratios, depending on the technology used in the country of broadcast. For 4:3 aspect-ratio broadcasts, the 640×480 format is used in NTSC countries, while the 720×576 format (rescaled to 768×576) is used in PAL countries. For 16:9 broadcasts, the 704×480 (rescaled to 848×480) format is used in NTSC countries, while the 720×576 format (rescaled to 1024×576) is used in PAL countries. However, broadcasters may choose to reduce these resolutions to save bandwidth. The perceived quality of such programming is surprisingly acceptable because of interlacing, wherein the effective vertical resolution is halved to 288 lines.

A broadcaster may opt to use a standard-definition digital signal instead of an HDTV signal, because current convention allows the bandwidth of a DTV channel to be subdivided into multiple subchannels, providing multiple feeds of entirely different programming on the same channel. With some implementations, image resolution may be less directly limited by bandwidth; for example in DVB-T, broadcasters can choose from several different modulation schemes, giving them the option to reduce the transmission bitrate and make reception easier for more distant or mobile viewers.

### BRIEF SUMMARY OF THE INVENTION

Audio signal adjusting devices and methods are provided. An exemplary embodiment of such an audio signal adjusting device for adjusting the amplitudes of a plurality of digital audio signals received from a decoder decoding a plurality of audio signals received from an antenna, comprises a buffer, a signal abnormality detector and a fading processor. The buffer stores the digital audio signals received from the decoder. The signal abnormality detector detects the abnormality of the digital audio signals stored in the buffer and outputs a fading out enable instruction when the digital audio signals are detected as abnormal. The fading processor fades out the amplitudes of the digital audio signals stored in the buffer according to a fading out algorithm after receiving the fading out enable instruction, to output a plurality of faded digital audio signals.

An exemplary embodiment of an audio signal adjusting method adjusting the amplitudes of a plurality of digital audio signals received from a decoder comprises: storing the digital audio signals in a buffer; detecting the abnormality of the digital audio signals stored in the buffer and outputting a fading out enable instruction when the digital audio signals are detected as abnormal; and fading out the amplitudes of the digital audio signals stored in the buffer according to a fading out algorithm after receiving the fading out enable instruction, to output a plurality of faded digital audio signals.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a block diagram in the receiving end of a DTV broadcasting system;

FIG. 2 illustrates a block diagram of an audio signal adjusting device in the receiving end of a DTV broadcasting system according to one embodiment of the invention;

FIG. 3 illustrates an example of the abnormality of the digital audio signal;

FIG. 4 illustrates another example of the abnormality of the digital audio signal;

FIG. 5 illustrates another example of the abnormality of the digital audio signal;

FIG. 6 illustrates another example of the abnormality of the digital audio signal;

FIG. 7 illustrates 32 exemplary PCM data stored in a buffer;

FIG. 8 illustrates another 32 exemplary PCM data stored in a buffer;

FIG. 9 illustrates a flow chart of the audio signal adjusting method according to one embodiment of the invention; and

FIG. 10 illustrates a flow chart of the audio signal adjusting method after fading out the digital audio signals according to one embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

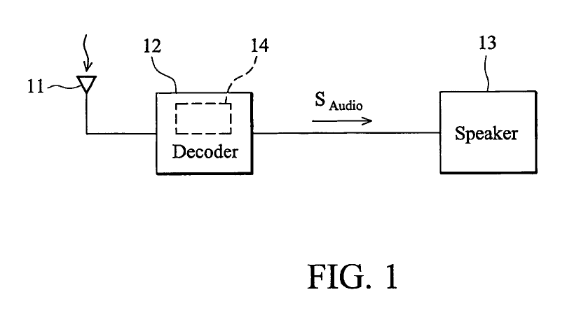

FIG. 1 is a block diagram in the receiving end of a DTV broadcasting system. As shown in FIG. 1, the broadcasted digital signals are received by an antenna 11 and are passed into a decoder 12. The decoder 12 decodes the received signals into the digital audio signals S_{Audio}, with standard format, for example, the digital audio signals S_{Audio} could be uniformly sampled pulse code modulation (PCM) signals with N-bits resolution. The decoded digital audio signals S_{Audio} are then passed to the speaker 13 for playing. In some DTVs, the decoder 12 further comprises a checking device 14 for checking the received digital audio signals, and the decoder 12 outputs the digital audio signals when the signal quality of the received digital audio signals is good enough or when the signal format of the received digital audio signals is correct. For example, when the parsed data size of the received digital audio signals is unreasonably small or large, the format of the received digital audio signals is regarded as incorrect. For another example, when the signal to noise ratio of the received digital audio signals is undesirable, the signal quality of the received digital audio signals is regarded as being in bad quality.

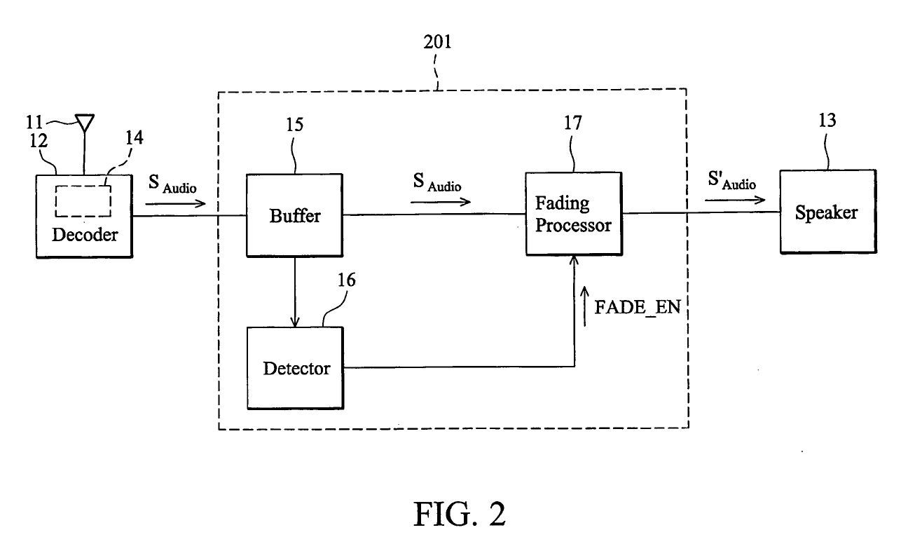

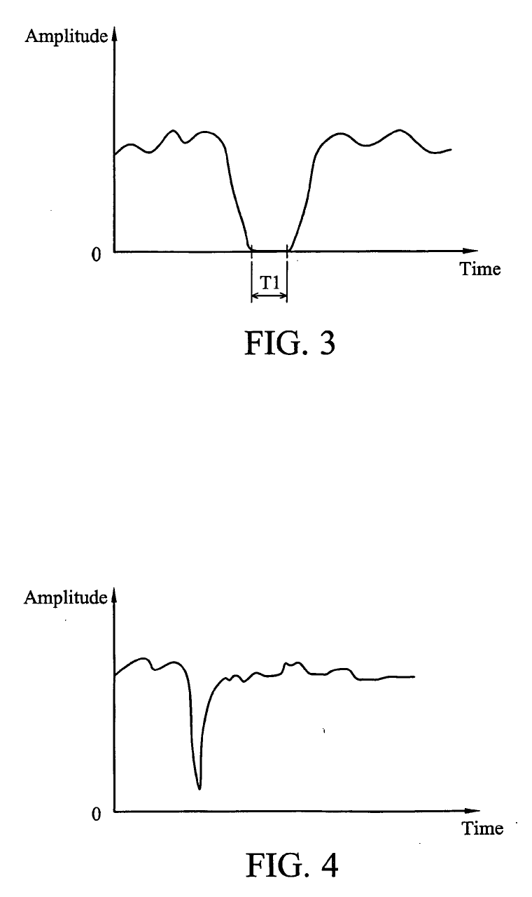

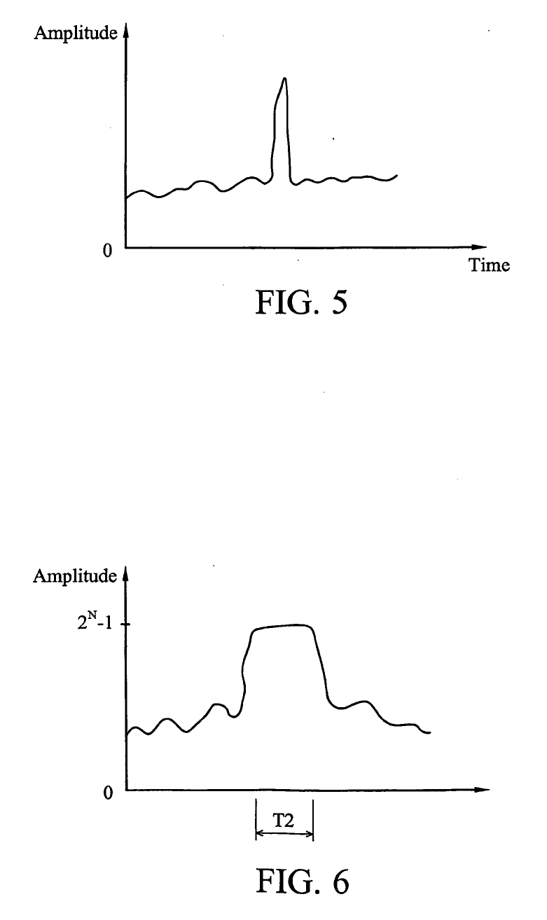

FIG. 2 illustrates a block diagram of an audio signal adjusting device 201 in the receiving end of a DTV broadcasting system according to one embodiment of the invention. As shown in FIG. 2, a buffer 15 is connected to the decoder 12 for storing the digital audio signals S_{Audio} received from the decoder 12. A signal abnormality detector 16 is connected to the buffer 15 for detecting the abnormality of the digital audio signals stored in the buffer according to a first decision rule, and outputting a fading out enable instruction FADE_EN when the digital audio signals are detected as abnormal. The first decision rule for judging that the digital audio signals are abnormal may be designed to analyze the signal characteristic, or to check the signal continuity, or may be designed to check any specific property of the digital audio signals according to different applications. According to one embodiment of the invention, the first decision rule could be that when the amplitudes of the digital audio signals stored in the buffer comprise a plurality of continuous zero values, as shown in the time period T1 in FIG. 3, the digital audio signals would be detected as abnormal. According to another embodiment of the invention, the first decision rule could be that when there is a sudden drop or sudden rise in the amplitudes of the digital audio signals stored in the buffer, as shown in FIG. 4 and FIG. 5, the digital audio signals would be detected as abnormal. According to another embodiment of the invention, the first decision rule could be that when the amplitudes of the digital audio signals stored in the buffer comprise an invalid PCM value, the digital audio signals would be detected as abnormal. For example, when the N-bit PCM is adopted, the invalid PCM value is the one beyond the range from 0 to (2^{N}−1). According to another embodiment of the invention, the first decision rule could be that when the amplitudes of the digital audio signals stored in the buffer comprise a plurality of continuous maximum PCM values, as shown in the time period T2 in FIG. 6, the digital audio signals would be detected as abnormal. For example, when the N-bit PCM is adopted, maximum PCM value is (2^{N}−1).

When there is some abnormality occurring in the digital audio signals, the discontinuous digital audio signals may become annoying and the listeners may feel quite uncomfortable. Thus, when the abnormality is detected, some process should be taken to make the digital audio signals remain pleasant. Referring back to FIG. 2, the audio signal adjusting device 201 further comprises a fading processor 17 for fading out the amplitudes of the digital audio signals stored in the buffer 15 according to a fading out algorithm after receiving the fading out enable instruction FADE_EN, to output a plurality of faded digital audio signals S′_{Audio}.

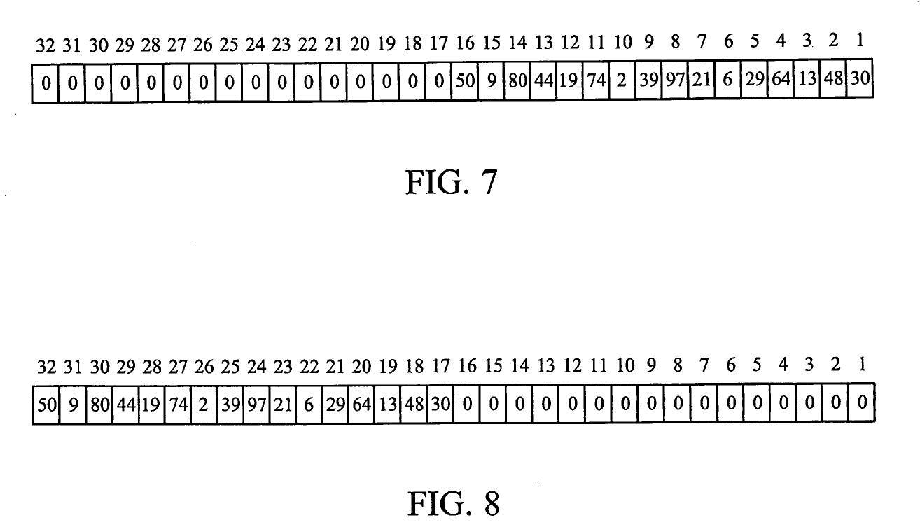

FIG. 7 illustrates 32 exemplary PCM data stored in a buffer 15. It should be understood that the buffer size used is to clearly explain the invention and the invention should not limited thereto. As shown in FIG. 7, the 1^{st}-16^{th} storing units store the PCM data with non-zero value, while the 17^{th}-32^{th} storing units store PCM data with zero values. Since there is a plurality of zero values stored in a buffer 15, the digital audio signals are detected as abnormal and signal abnormality detector 16 outputs fading out enable instruction FADE_EN to the fading processor 17. According to one embodiment of the invention, the fading out algorithm is to gradually decrease the amplitudes of the digital audio signals according to a decreasing factor. The decreasing factor can be a factor smaller than one, for example, the decreasing factor can be 0.9, 0.8, . . . etc. Alternatively, the decreasing factor could be a curve with unevenly distributed decreasing values. It should be understood that there are a plurality fading out algorithms and the invention should not limited thereto. Taking 0.9 as an example, the fading algorithm is processed as:
faded output [1]=30*0.9̂1.
faded output [2]=48*0.9̂2.
faded output [3]=13*0.9̂3
. . . .
faded output [16]=50*0.9̂16.
faded output [17]=0
. . . .
faded output [32]=0.
   Thus, after fading out the amplitudes of the digital audio signals S_{Audio} in the buffer 15, the amplitudes of the faded digital audio signals S′_{Audio} are decreased and gradually approach zero. In this way, the audience will not be shocked by the sudden change in the original digital audio signals S_{Audio} and the abnormal digital audio signals are more pleasant.

After the signal abnormality detector 16 outputs the fading out enable instruction, the signal abnormality detector further detects whether the digital audio signals have become normal and outputs a fading out disable instruction FADE_DIS when the digital audio signals are detected as normal according to a second decision rule. According to one embodiment, the second decision rule should be designed to correspond to the first decision rule. For example, when the first decision rule is designed to detect whether the amplitudes of the digital audio signals stored in the buffer comprise a plurality of continuous zero values, the second decision rule is designed to detect whether the amplitudes of the digital audio signals comprise a plurality of continuous non-zero values. When the first decision rule is designed to detect whether there is a sudden drop or sudden rise in the amplitudes of the digital audio signals, the second decision rule is designed to detect whether there is no sudden drop or sudden rise, over a predetermined period of time, in the amplitudes of the digital audio signals. When the first decision rule is designed to detect whether the amplitudes of the digital audio signals comprise an invalid PCM value, the second decision rule is designed to detect whether the amplitudes of the digital audio signals comprise no invalid PCM value over a predetermined period of time. When the first decision rule is designed to detect whether the amplitudes of the digital audio signals comprises a plurality of continuous maximum PCM values, the second decision rule is designed to detect whether the amplitudes of the digital audio signals comprises no continuous maximum PCM values over a predetermined period of time.

After receiving the fading out disable instruction FADE_DIS, the fading processor 17 further fades in the amplitudes of the digital audio signals stored in the buffer according to a fading in algorithm. FIG. 8 illustrates another 32 exemplary PCM data stored in a buffer 15. As shown in FIG. 8, the 1^{st}-16^{th} storing units store the PCM data with zero values, while the 17^{th}-32^{th} storing units store PCM data with non-zero values. Since there is no zero value after the 17^{th} storing unit, the digital audio signals are detected as normal and signal abnormality detector 16 outputs fading out disable instruction FADE_DIS to the fading processor 17. According to one embodiment of the invention, the fading out algorithm is to gradually increase the amplitudes of the digital audio signals according to an increasing factor. The increasing factor can be a factor larger than one, for example, the increasing factor can be 0.9̂−1, 0.8´−1, . . . etc. Alternatively, the increasing factor could be a curve with unevenly distributed increasing values. It should be understood that there are a plurality fading in algorithms and the invention should not limited thereto. Taking 0.9̂−1 as an example, the fading algorithm is processed as:
faded output [16]=0,
faded output [17]=30*0.9̂16,
faded output [18]=48*0.9̂15
. . . ,
faded output [31]=9*0.9̂2,
faded output [32]=50*0.9̂1.
   Thus, after fading in the amplitudes of the digital audio signals S_{Audio} in the buffer 15, the amplitudes of the faded digital audio signals S′_{Audio} are increased and gradually approach the original values.

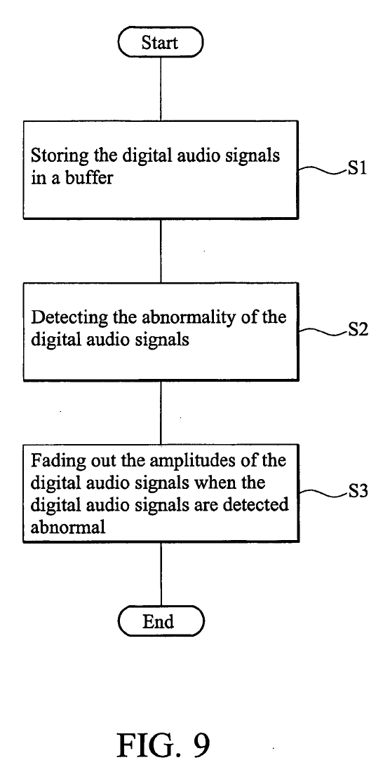

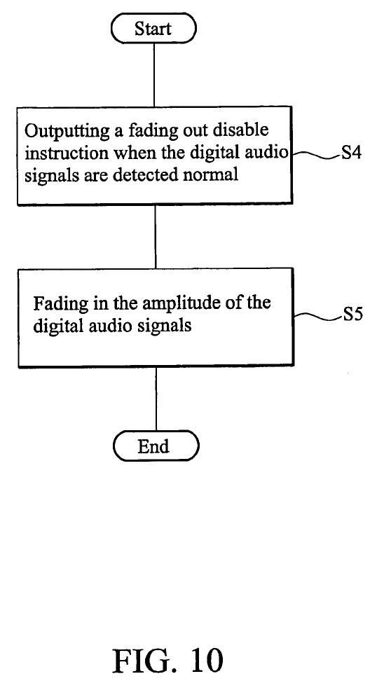

FIG. 9 illustrates a flow chart of the audio signal adjusting method according to one embodiment of the invention. Firstly, the digital audio signals are stored in a buffer (S1). Next, the abnormality of the digital audio signals stored in the buffer is detected according to a first decision rule, a fading out enable instruction is outputted when the digital audio signals are detected as abnormal (S2). Finally, the amplitudes of the digital audio signals stored in the buffer are faded out according to a fading out algorithm after receiving the fading out enable instruction (S3), to output a plurality of faded digital audio signals. FIG. 10 illustrates a flow chart of the audio signal adjusting method after fading out the digital audio signals according to one embodiment of the invention. Firstly, the normality of the digital audio signals is detected according to a second decision rule and a fading out disable instruction is outputted when the digital audio signals are detected as normal (S4). Finally, the amplitudes of the digital audio signals stored in the buffer are faded in according to a fading in algorithm after receiving the fading out disable instruction (S5).

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. An audio signal adjusting device, for adjusting the amplitudes of a plurality of digital audio signals received from a decoder, wherein the decoder decodes a plurality of audio signals received from an antenna and outputs the digital audio signals, comprising:
a buffer for storing the digital audio signals received from the decoder;
a signal abnormality detector for detecting the abnormality of the digital audio signals stored in the buffer and outputting a fading out enable instruction when the digital audio signals are detected as abnormal; and
a fading processor for fading out the amplitudes of the digital audio signals stored in the buffer according to a fading out algorithm after receiving the fading out enable instruction, to output a plurality of faded digital audio signals.

2. The audio signal adjusting device as claimed in claim 1, wherein when the amplitudes of the digital audio signals stored in the buffer comprise a plurality of continuous zero values, the digital audio signals are detected as abnormal.

3. The audio signal adjusting device as claimed in claim 1, wherein when there is a sudden drop in the amplitudes of the digital audio signals stored in the buffer, the digital audio signals are detected as abnormal.

4. The audio signal adjusting device as claimed in claim 1, wherein when there is a sudden rise in the amplitudes of the digital audio signals stored in the buffer, the digital audio signals are detected as abnormal.

5. The audio signal adjusting device as claimed in claim 1, wherein the fading out algorithm is to gradually decrease the amplitudes of the digital audio signals according to a decreasing factor.

6. The audio signal adjusting device as claimed in claim 1, wherein after the signal abnormality detector outputs the fading out enable instruction, the signal abnormality detector further outputs a fading out disable instruction when the digital audio signals are detected as normal.

7. The audio signal adjusting device as claimed in claim 6, wherein the fading processor further fades in the amplitudes of the digital audio signals stored in the buffer according to a fading in algorithm after receiving the fading out disable instruction.

8. The audio signal adjusting device as claimed in claim 6, wherein when the amplitudes of the digital audio signals stored in the buffer comprises a plurality of continuous non-zero values, the digital audio signals are detected as normal.

9. The audio signal adjusting device as claimed in claim 6, wherein when there is no sudden drop and sudden rise, over a predetermined period of time, in the amplitudes of the digital audio signals stored in the buffer, the digital audio signals are detected as normal.

10. The audio signal adjusting device as claimed in claim 6, wherein the fading in algorithm is to gradually increase the amplitudes of the digital audio signals according to an increasing factor.

11. The audio signal adjusting device as claimed in claim 1, wherein the digital audio signals are the audio signals in a digital television broadcasting system.

12. The audio signal adjusting device as claimed in claim 1, wherein the digital audio signals are the pulse code modulation (PCM) signals.

13. The audio signal adjusting device as claimed in claim 12, wherein when the amplitudes of the digital audio signals stored in the buffer comprise an invalid PCM value, the digital audio signals are detected as abnormal.

14. The audio signal adjusting device as claimed in claim 12, wherein when the amplitudes of the digital audio signals stored in the buffer comprise a plurality of continuous maximum PCM values, the digital audio signals are detected as abnormal.

15. An audio signal adjusting method adjusting the amplitudes of a plurality of digital audio signals received from a decoder decoding a plurality of audio signals received from an antenna and outputting the digital audio signals, comprising:
storing the digital audio signals in a buffer;
detecting the abnormality of the digital audio signals stored in the buffer and outputting a fading out enable instruction when the digital audio signals are detected as abnormal; and
fading out the amplitudes of the digital audio signals stored in the buffer according to a fading out algorithm after receiving the fading out enable instruction, to output a plurality of faded digital audio signals.

16. The audio signal adjusting method as claimed in claim 15, wherein when the amplitudes of the digital audio signals stored in the buffer comprise a plurality of continuous zero values, the digital audio signals are detected as abnormal.

17. The audio signal adjusting method as claimed in claim 15, wherein when there is a sudden drop in the amplitudes of the digital audio signals stored in the buffer, the digital audio signals are detected as abnormal.

18. The audio signal adjusting method as claimed in claim 15, wherein when there is a sudden rise in the amplitudes of the digital audio signals stored in the buffer, the digital audio signals are detected as abnormal.

19. The audio signal adjusting method as claimed in claim 15, wherein the fading out algorithm is to gradually decrease the amplitudes of the digital audio signals according to a decreasing factor.

20. The audio signal adjusting method as claimed in claim 15, further comprising outputting a fading out disable instruction when the digital audio signals are detected as normal after outputting the fading out enable instruction.

21. The audio signal adjusting method as claimed in claim 20, further comprising fading in the amplitudes of the digital audio signals stored in the buffer according to a fading in algorithm after receiving the fading out disable instruction.

22. The audio signal adjusting method as claimed in claim 20, wherein when the amplitudes of the digital audio signals stored in the buffer comprise a plurality of continuous non-zero values, the digital audio signals are detected as normal.

23. The audio signal adjusting method as claimed in claim 20, wherein when there is no sudden drop and sudden rise, over a predetermined period of time, in the amplitudes of the digital audio signals stored in the buffer, the digital audio signals are detected as normal.

24. The audio signal adjusting device as claimed in claim 20, wherein the fading in algorithm is to gradually increase the amplitudes of the digital audio signals according to an increasing factor.

25. The audio signal adjusting device as claimed in claim 15, wherein the digital audio signals are the audio signals in a digital television broadcasting system.
